(19) United States
(12) Patent Application Publication
(10) Pub. No.: US 2026/0114196 A1
(43) Pub. Date: Apr. 23, 2026

(54) METHOD OF FORMING A STRUCTURE INCLUDING SILICON NITRIDE

(71) Applicant: ASM IP Holding B.V., Almere (NL)

(72) Inventors: Ryoko Yamada, Odawara-shi (JP); Umar Sidik, Tokyo (JP); Agung Setiadi, Tokyo (JP); Musa Alaydrus, Helsinki (FI); Annisa Noorhidayati, Tokyo (JP); Jun Yoshikawa, Tokyo (JP)

(21) Appl. No.: 19/357,299

(22) Filed: Oct. 14, 2025

Related U.S. Application Data
(60) Provisional application No. 63/708,426, filed on Oct. 17, 2024.

(51) Int. Cl. H01L 21/02; C23C 16/34; C23C 16/455; C23C 16/56; H01L 21/311

(52) U.S. Cl. CPC H10P 14/69433; C23C 16/345; C23C 16/45536; C23C 16/56; H10P 14/6336; H10P 14/6339; H10P 14/6544; H10P 50/283

(57) ABSTRACT

Methods of forming a structure that include non-conformal silicon nitride overlaying a feature are disclosed. An exemplary method includes using a plasma deposition process, depositing silicon nitride onto the top, the bottom, and the sidewall of the feature and optionally treating the deposited silicon nitride. The deposition process and/or the treatment process can affect the deposited silicon nitride, such that after an etch process, the silicon nitride is preferentially removed from the bottom of the feature, such that the structure includes silicon nitride on the top and on the sidewall of the feature and includes no or relatively little silicon nitride on the bottom of the feature.

### CROSS-REFERENCE TO RELATED APPLICATIONS

This application claims priority to U.S. Provisional Patent Application Ser. No. 63/708,426 filed Oct. 17, 2024, and titled METHOD OF FORMING A STRUCTURE INCLUDING SILICON NITRIDE, the disclosure of which is hereby incorporated by reference in its entirety.

### FIELD OF INVENTION

The present disclosure generally relates to methods of depositing material and to structures including the deposited material. More particularly, the disclosure relates to methods of forming structures that include silicon nitride and to structures including such material.

### BACKGROUND OF THE DISCLOSURE

Silicon nitride films are used for a wide variety of applications. For example, silicon nitride films can be used to form insulating layers, etch stop layers, etch-resistant protective regions, spacers, and the like, on structures formed during formation of electronic devices.

To form the regions or features including silicon nitride, a silicon nitride film is typically deposited onto a surface of a substrate. Portions of the deposited film are then typically etched to remove some of the silicon nitride to form desired features or areas including the remaining silicon nitride material. For example, during formation of spacers, a silicon nitride film is typically conformally deposited on a substrate surface that includes gaps. The gaps include a top surface, a bottom surface, and a sidewall therebetween. The silicon nitride that is deposited on the top and bottom surfaces of the gaps can be selectively removed using anisotropic etching techniques. While such techniques can work for some applications, in some cases, a film quality on the bottom surface can be higher (e.g., the film can be denser). In such cases, more material than is desired can be removed from the sidewall during an etch process. Accordingly, improved methods for forming structures including silicon nitride are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to methods that can be used to selectively form silicon nitride on a sidewall of a feature relative to a bottom surface of the feature. While the ways in which various embodiments of the present disclosure address drawbacks of prior methods are discussed in more detail below, in general, various embodiments of the disclosure provide improved methods of depositing silicon nitride overlying features on a surface of a substrate and selectively removing the silicon nitride at the bottom of the features relative to the top and the sidewall of the features.

In accordance with various embodiments of the disclosure, a method of forming a structure includes steps of providing a substrate within a reaction chamber, the substrate comprising a feature on a surface of the substrate, the feature comprising a top, a bottom, and a sidewall therebetween; using a plasma deposition process, depositing silicon nitride onto the top, the bottom, and the sidewall of the feature; and selectively removing the silicon nitride at the bottom of the feature relative to the top and the sidewall of the feature. In accordance with examples of these embodiments, after the step of selectively removing the silicon nitride at the bottom, the silicon nitride is removed from the bottom of the feature, and the structure comprises silicon nitride on the top and on the sidewall of the feature. In accordance with further examples, the step of selectively removing comprises a wet etch process. In accordance with further examples, the plasma deposition process is or includes a cyclical plasma deposition process. In accordance with examples of the disclosure, the cyclical deposition process includes one or more deposition cycles, each deposition cycle including pulsing a silicon precursor to the reaction chamber for a precursor pulse, providing a reactant gas comprising hydrogen and nitrogen, and after the precursor pulse, providing plasma power within the reaction chamber to form a plasma. The gas comprising hydrogen and nitrogen can be provided continuously to the reaction chamber through two or more deposition cycles. In accordance with further examples of the disclosure, the cyclical process includes continuously providing a gas comprising nitrogen to the reaction chamber and pulsing a gas comprising hydrogen to the reaction chamber—e.g., for about the same period of time as the silicon precursor is pulsed to the reaction chamber. In accordance with further examples, the method further includes a treatment process—e.g., after the deposition process is completed. The treatment process can be a singular step or can include two or more steps. In some cases, the treatment process includes a step of forming a plasma from a treatment gas comprising nitrogen. In some cases, the treatment process includes a first (e.g., reverse topological treatment (RTT) step of forming a plasma from a treatment gas comprising hydrogen and nitrogen and a second (e.g., reconstruction treatment (RT)) step of forming a plasma from a gas comprising nitrogen. A power used to form a plasma during a treatment process can be less than the plasma power used during deposition. Further, in a multi-step treatment process, a power during a first treatment step can be less than the plasma power used during deposition and power during a second treatment step can be less than or equal to the plasma power used during the first treatment step.

In accordance with additional embodiments of the disclosure, a method of forming a structure includes providing a substrate within a reaction chamber, the substrate comprising a feature on a surface of the substrate, the feature comprising a top, a bottom, and a sidewall therebetween; using a plasma deposition process, (e.g., conformally) depositing silicon nitride onto the top, the bottom, and the sidewall of the feature; and selectively removing the silicon nitride at the bottom of the feature relative to the top and sidewall of the feature, such that the silicon nitride is removed or substantially removed at the bottom of the feature and remains at the top and the sidewall of the feature, wherein the plasma deposition process comprises providing power having a frequency between about 13 MHz (e.g., greater than 13.56 MHz) and about 100 MHz. The method can include a treatment process as described above or elsewhere herein.

In accordance with embodiments described herein, an ion energy of a plasma during the plasma deposition and/or all or at least part of the treatment process is greater at the bottom of the feature than at the top of the feature. Additionally, or alternatively, ion scattering during a treatment process is greater at the top of the feature than at the bottom of the feature. In accordance with further embodiments, the treatment process can be used to form intermediate structures that include a silicon nitride layer that exhibits a higher etch rate at a bottom of a feature, relative to a top and sidewall of the feature.

In accordance with additional embodiments of the disclosure, a structure is provided. The structure can include a substrate comprising a feature on a surface of the substrate, the feature comprising a top, a bottom, and a sidewall therebetween. The silicon nitride layer can be formed using a method described herein. The structure can include silicon nitride selectively formed on a top and sidewall of a feature relative to the bottom of the feature.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with at least one embodiment of the disclosure.

FIG. 2 illustrates a timing sequence in accordance with at least one embodiment of the disclosure.

FIG. 3 illustrates transmission electron microscopy (TEM) images of structures formed in accordance with at least one embodiment of the disclosure.

FIG. 4 illustrates additional TEM images of structures formed in accordance with at least one embodiment of the disclosure.

FIG. 5 illustrates etched amount values versus plasma power in accordance with at least one embodiment of the disclosure.

FIG. 6 illustrates position information for use with FIGS. 7 and 8.

FIG. 7 illustrates ion energy versus position in accordance with embodiments of the disclosure.

FIG. 8 illustrates ion flux versus position in accordance with at least one embodiment of the disclosure.

FIG. 9 illustrates a portion of a substrate that includes an exemplary feature in accordance with examples of the disclosure.

FIG. 10 illustrates structures formed in accordance with additional examples of the disclosure.

FIG. 11 illustrates a timing sequence in accordance with additional examples of the disclosure.

FIG. 12 illustrates TEM images of structures formed in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses of the invention and obvious modifications and equivalents thereof. Thus, it is intended that the scope of the invention disclosed should not be limited by the particular disclosed embodiments described below.

Exemplary embodiments of the disclosure provide improved methods for forming a structure that includes silicon nitride on a sidewall of a feature. Exemplary methods can be used to selectively form silicon nitride on the sidewall and a top of the feature relative to a bottom of the feature.

In this disclosure, a gas can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a noble gas. In some cases, the term precursor can refer to a compound that participates in the chemical reaction that produces another compound, and particularly to a compound that constitutes a film matrix or a main skeleton of a film. In some cases, the term reactant can be used to refer to a compound or gas that reacts with the precursor or derivative thereof to form a film or portion thereof. In some cases, the term reactant can be used interchangeably with the term precursor. The term inert gas can refer to a gas that does not take part in a chemical reaction and/or does not become a part of a film matrix to an appreciable extent. Exemplary inert gases include He, Ar, H₂, N₂ (e.g., when not activated by a plasma) and any combination thereof.

As used herein, the term substrate can refer to any underlying material or materials that may be used to form, or upon which, a device, a circuit, or a film may be formed. A substrate can include a bulk material, such as silicon (e.g., single-crystal silicon) and can include one or more layers overlying the bulk material. Further, the substrate can include various topologies, such as recesses, lines, and the like formed within or on at least a portion of a layer of the substrate. In accordance with particular examples, the substrate comprises one or more features, wherein each feature includes a top, a bottom, and a sidewall spanning between the top and the bottom.

As used herein, the term film and/or layer can refer to any continuous or non-continuous material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material with pinholes, which may be at least partially continuous. Alternatively, a film or layer may consist entirely of isolated islands.

As used herein, the term cyclical deposition process may refer to a process that includes sequential introduction of precursors and/or reactants into a reaction chamber and/or sequential plasma power pulses to deposit a layer over a substrate. Cyclical deposition processes include processing techniques, such as atomic layer deposition (ALD), cyclical chemical vapor deposition (CCVD), and plasma-enhanced ALD and CCVD. For example, a cyclical process can include continually providing a precursor or reactant to a reaction chamber and pulsing the other of the precursor and reactant. Additionally or alternatively, a cyclical plasma deposition process can include pulsing a plasma power during the deposition process.

As used herein, the term cyclical chemical vapor deposition may refer to any process wherein a substrate is sequentially exposed to two or more volatile precursors/reactants, which react and/or decompose on a substrate to produce a desired deposition.

A layer including silicon nitride (SiN) can comprise, consist essentially of, or consist of silicon nitride material. Films consisting of silicon nitride can include an acceptable amount of impurities, such as carbon, chlorine or other halogen, and/or hydrogen, which may originate from one or more precursors used to deposit the silicon nitride layers. As used herein, SiN or silicon nitride refers to a compound that includes silicon and nitrogen. SiN can be represented as SiNₓ, where x varies from, for example, about 0.5 to about 2.0, where some Si—N bonds are formed. In some cases, x may vary from about 0.9 to about 1.7, from about 1.0 to about 1.5, or from about 1.2 to about 1.4. In some embodiments, silicon nitride is formed where Si has an oxidation state of +IV and the amount of nitride in the material may vary.

As used herein, a structure can include a substrate as described herein. Structures can include one or more layers overlying the substrate, such as one or more layers formed according to a method as described herein.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. For example, the term about can refer to +/−20, 10, 5, 2, or 1 percent of a value, and any value noted herein can be +/−20, 10, 5, 2, or 1 percent of the value. Further, in this disclosure, the terms including, constituted by and having can refer independently to typically or broadly comprising, comprising, consisting essentially of, or consisting of in some embodiments. It shall be understood that when a composition, method, device, or the like is said to comprise certain features, it means that it includes those features, and that it does not necessarily exclude the presence of other features, as long as they do not render the claim unworkable. This notwithstanding, the term comprises or includes or can include the meaning of consists of, i.e., the case when the composition, method, device, or the like in question only includes the features, components, and/or steps that are listed, and does not contain any other features, components, steps, and the like, and includes consisting essentially of.

In this disclosure, any defined meanings do not necessarily exclude ordinary and customary meanings in some embodiments.

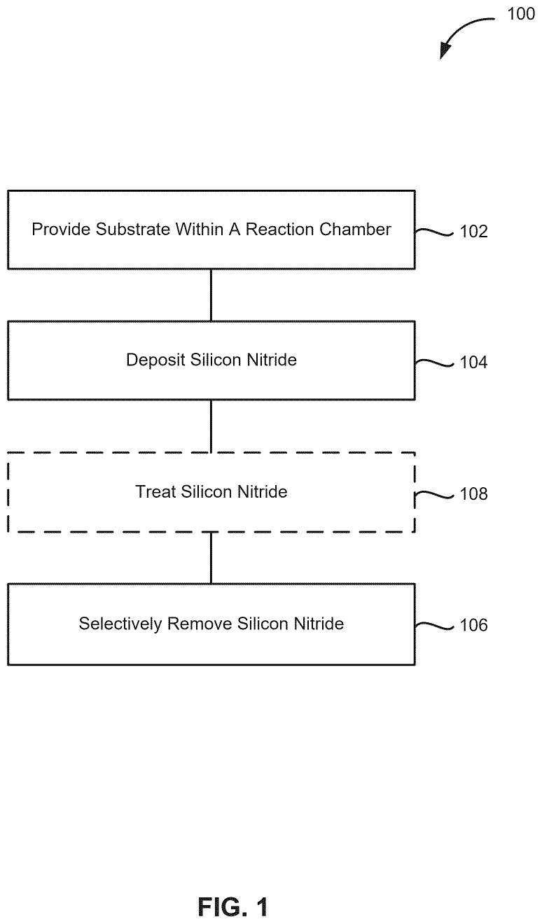

Turning now to the figures, FIG. 1 illustrates a method 100 of forming a structure in accordance with embodiments of the disclosure. In the illustrated example, method 100 includes the steps of providing a substrate within a reaction chamber (102), depositing silicon nitride (104), selectively removing the silicon nitride (106), and optionally treating the silicon nitride (108).

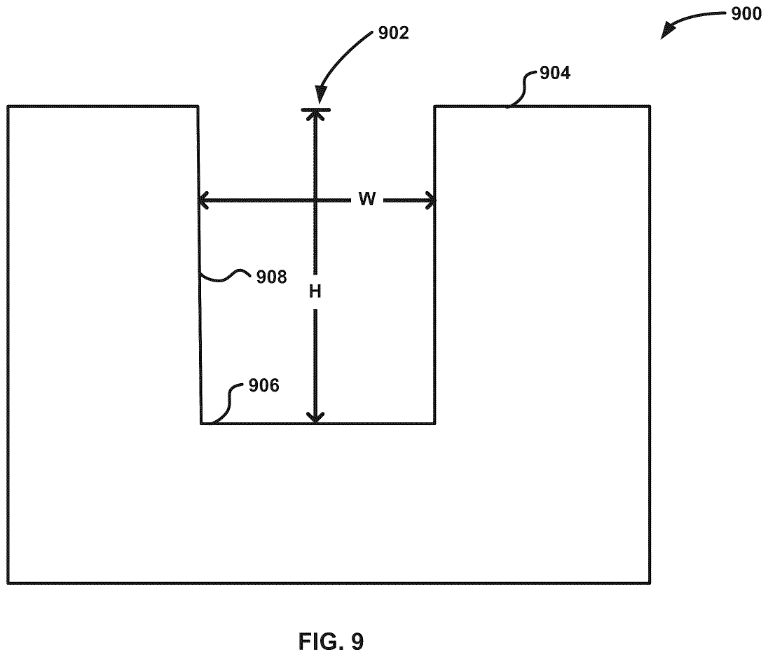

During step 102, a substrate is provided into a reaction chamber of a reactor. In accordance with examples of the disclosure, the substrate includes one or more features on a surface of the substrate. The feature(s) can be or include, for example, a gap, a via, a trench, or the like. FIG. 9 illustrate a portion 900 of a substrate that includes an exemplary feature 902. Feature 902 includes a top 904, a bottom 906, and a sidewall 908 therebetween. An aspect ratio (e.g., a ratio of a height H to a width W) of feature 902 can be from, for example, about 0.5 to about 30 or about 2 to about 10.

During step 102, the substrate can be brought to a desired temperature and pressure for step 104. By way of examples, a temperature (e.g., of a substrate or a substrate support) within a reaction chamber can be between about 50° C. and about 1000° C. or about 100° C. and about 600° C. A pressure within the reaction chamber can be between about 0.5 and about 50 Torr or between about 0.5 and about 30 Torr or between about 0.5 and about 10 Torr.

During step 104, silicon nitride is deposited onto the top, the bottom, and the sidewall of the feature (e.g., top 904, bottom 906, and sidewall 908) using a plasma deposition process. In accordance with examples of the disclosure, the plasma deposition process is or includes a cyclical plasma deposition process. The cyclical plasma deposition process can include pulsing a silicon precursor to the reaction chamber for a precursor pulse, providing a reactant gas (e.g., comprising hydrogen and/or nitrogen), and after (e.g., after the beginning or cessation of) the precursor pulse, providing plasma power within the reaction chamber to form a plasma.

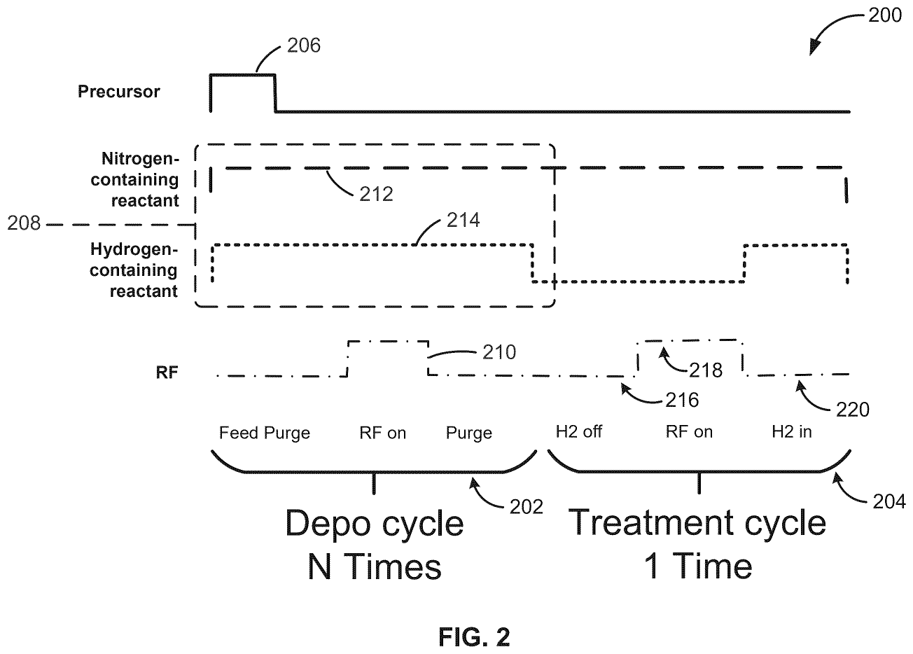

FIG. 2 illustrates an exemplary timing sequence 200 suitable for use with step 104 and optional treatment process 108. As illustrated, timing sequence 200 includes a deposition cycle 202 and a treatment cycle 204. Deposition cycle 202 can correspond to step 104 and treatment cycle 204 can correspond to treatment process 108. In accordance with examples of the disclosure, deposition cycle 202 is repeated one or two or more times (e.g., 5 or more times) prior to timing sequence 200 proceeding to treatment cycle 204. Timing sequence 200—i.e., one or more deposition cycles 202 and at least one treatment cycle 204—can also be repeated one or more times prior to method 100 proceeding to step 106. In some cases, the deposited silicon nitride is conformal.

In the illustrated example in FIG. 2, each deposition cycle includes pulsing or providing a silicon precursor to the reaction chamber for a precursor pulse period (period 206), providing a reactant gas to the reaction chamber (period 208), and providing a deposition plasma power for a deposition plasma period to form activated species from the reactant gas (period 210).

During period 206, the silicon precursor is pulsed to the reaction chamber. Exemplary silicon precursors suitable for use with step 104/period 206 include halogenated silicon compounds, such as silicon compounds comprising one or more of Cl and I. Particular examples include trichlorodisilane (Si₂Cl₃H₃), pentachlorodisilane (Si₂Cl₅H), hexachlorodisilane (Si₂Cl₆), octachlorotrisilane (Si₃Cl₈), dichlorosilane (SiCl₂H₂), dimethyldichlorosilane (SiCl₂Me₂), tetrachlorosilane (SiCl₄), tetraiodosilane (SiI₄), triiodosilane (SiI₃H), diiodosilane (SiI₂H₂), or the like.

A flowrate of the silicon precursor with a carrier gas to the reaction chamber during period 206 can be about 200 to about 10000 or about 2000 to about 4000 sccm. A duration of the silicon precursor pulse can be between about 0.01 second to 60 seconds, 0.1 second to 60 seconds, 0.1 second to 20 seconds, or 0.1 second to 5 seconds.

During period 208, one or more of a hydrogen-containing reactant and/or a nitrogen-containing reactant, i.e., a reactant gas comprising hydrogen and nitrogen, is provided during periods 212, 214, respectively. Exemplary nitrogen-containing reactants include one or more of nitrogen (N₂), NH₃, N₂—H₂ or the like, alone or in combination with one or more of argon (Ar), helium (He), or the like in any combination. Exemplary hydrogen-containing reactants include one or more of nitrogen (H₂), NH₃, N₂—H₂ or the like, alone or in combination with one or more of argon (Ar), helium (He), or the like in any combination.

A flowrate of the nitrogen-containing reactant to the reaction chamber during period 208 can be about 1000 to about 50000 or about 10000 to about 30000 sccm. A flowrate of the hydrogen-containing reactant to the reaction chamber during period 208 can be about 0.1 to about 500 or about 1 to about 300 or about 50 to 150 sccm.

A duration of a reactant pulse can be between about 1 and about 30 seconds or between about 2 and about 10 seconds and/or as illustrated, can be continuous through one or more deposition cycles 202. In this illustrated example, the nitrogen-containing period 212 is continuous through one or two or more deposition and treatment cycles. In accordance with further examples, the hydrogen-containing period 214 is continuous through one or two or more deposition cycles and then ceases prior to a treatment cycle.

During period 210, a deposition plasma power is provided for a deposition plasma period to form activated species from the reactant gas. The deposition plasma power can have a frequency of between about 13 MHz and about 100 MHz or between about 14 MHz and about 100 MHz or between about 40 MHz and about 80 MHz or can be about 60 MHz. The deposition plasma power can have a power of between about 10 and about 2000 W or between about 800 and about 2000 W for a 300 mm diameter substrate or have similar power densities for substrates of different cross-sectional dimensions. For example, period 210 can include providing deposition plasma power having a power density between 0.01 and about 0.03 W/mm² of substrate size. A duration of period 210 can be between about 0.05 seconds and about 60 seconds or between about 0.5 seconds and about 30 seconds, or between about 5 seconds and about 15 seconds.

With reference again to FIG. 1, once a desired amount of silicon nitride is deposited (e.g., a desired number of cycles are performed), a treatment process can be performed. The treatment process includes treating the deposited silicon nitride in the reaction chamber or in another reaction chamber to form (treated) silicon nitride.

With reference again to FIG. 2 and timing sequence 200, an exemplary treatment cycle 204 includes a first period 216 in which the nitrogen-containing reactant and not the hydrogen-containing reactant are flowed to the reaction chamber, a second period 218, in which plasma power is provided, and can include a third period 220 in which the nitrogen-containing reactant and the hydrogen-containing reactant are flowed to the reaction chamber.

The nitrogen-containing reactant and the hydrogen-containing reactant provided during treatment step 204 can include nitrogen-containing reactant and the hydrogen-containing reactant or can include a different nitrogen-containing reactant and/or hydrogen-containing reactant selected from respective lists of such reactants. A flowrate and a duration of flow for each of the nitrogen-containing reactant and the hydrogen-containing reactant can be as described above. A temperature and pressure within the reaction chamber (e.g., of a susceptor within the reaction chamber) during cycles 202, 204 can be as noted above in connection with step 102.

During first period 216, the nitrogen-containing reactant is provided to the reaction chamber. During this period, the hydrogen-containing reactant flow is ceased. As illustrated, the nitrogen-containing reactant can be flowed continuously during the one or more deposition cycles 202 and the treatment cycle 204.

During second period 218, the nitrogen-containing reactant is provided to the reaction chamber and the hydrogen-containing reactant is not provided to the reaction chamber. Further, during second period 218, a treatment plasma power is provided for a treatment plasma period to form activated species from the treatment gas. The treatment plasma power can have a frequency of between about 100 kHz and about 80 MHz and/or between about 50 MHz and about 70 MHz. The treatment plasma power can have a power of between about 10 and about 2000 W or between about 100 and about 900 W or be about 600 W for a 300 mm diameter substrate or have similar power densities for substrates of different cross-sectional dimensions. A duration of second period 218 can be between about 0.05 seconds and about 300 seconds or between about 0.5 seconds and about 60 seconds. In accordance with examples of the disclosure, the deposition plasma power provided during period 210 is greater than the treatment plasma power provided during second period 218. In accordance with further examples, a duration of the deposition plasma period 210 is greater than a duration of second period 218. For example, the deposition plasma period can be greater than 50 or greater than 75 or greater than 100 and/or less than 300 or less than 200 percent of a duration of second period 218.

During third period 220, the flow of the hydrogen-containing reactant can resume. The hydrogen containing reactant and a flowrate of the hydrogen containing reactant can be as described above. A duration of third period 220 can be between about 0.001 and about 20 seconds or between about 0.05 and about 10 seconds.

Table 1 below illustrates particular exemplary process conditions suitable for use with method 100 and/or timing sequence 200. As illustrated by the tabulated date, method 100 and/or sequence 200 can include a presoak period and/or an inert gas activation step.

TABLE 1

| | | Inert | Bulk | |
|---|---|---|---|---|
| Step | Presoak | Activation | 5D | 1T |
| Blanket cycle number | 30 | 16 | XX | |
| H₂ (sccm) | 100 | 100 | 6 | 0 |
| Ar (slm) | 0 | 2.8 | 0 | 0 |
| N₂ (slm) | 9.8 | 9.8 | 19 | 19 |
| Carrier N₂ (slm) | 6 | 6 | 6 | 6 |
| Seal N₂ (slm) | 3 | 3 | 3 | 3 |
| RF power (W) | — | 1500 | 1800 | 1000 |
| RC Press (Torr) | 18.75 | 18.75 | 6 | 6 |
| Gap [mm] | 4 | 4 | 4 | 4 |
| Feed (s) | 3 | 3 | 3 | — |
| Purge (s) | 1 | 1 | 1 | — |
| H₂ OFF (s) | — | — | — | 1 |
| RF on (s) | — | 10 | 20 | 10 |
| H₂ IN (s) | — | — | — | 0.1 |
| Post Purge (s) | 0.1 | 0.1 | 0.1 | — |

Although not separately illustrated, during a presoak period as set forth in Table 1, the precursor, as described above in connection with period 206, can be provided for a number of cycles. The number of cycles can be, for example, between 1 and 100 or between 2 and 60. A pressure within the reaction chamber during the presoak period can be higher than the pressure during cycle 202 or 206. For example, a pressure can be between 1.5 and 5 or between 2 and 4 times higher during the presoak period, compared to cycles 202, 204. During the presoak period, the nitrogen-containing reactant and the hydrogen-containing reactant can be flowed to the reaction chamber. The flowrate of the hydrogen-containing reactant can be significantly higher than the flowrate of the hydrogen-containing reactant during period 214. Specific exemplary conditions are set forth in Table 1.

Returning again to FIG. 1, during step 106, silicon nitride (e.g., treated silicon nitride) at the bottom of the feature is selectively removed/etched relative to silicon nitride on the top and the sidewall of the feature. For example, after the step of selectively removing the silicon nitride at the bottom, the silicon nitride can be removed from the bottom of the feature, while the silicon nitride remains on the top and on the sidewall of the feature.

Exemplary etch processes suitable for step 106 include wet etch processes, such as a 100:1 dilute hydrofluoric acid etch process. Such etch processes are typically considered isotropic. However, as illustrated below, step 106 preferably removes silicon nitride from the bottom of the feature, relative to the top and sidewall of the feature. A duration of step 106 can be, for example, about 1 second to about 10 minutes or about 1 minute to about 5 minutes.

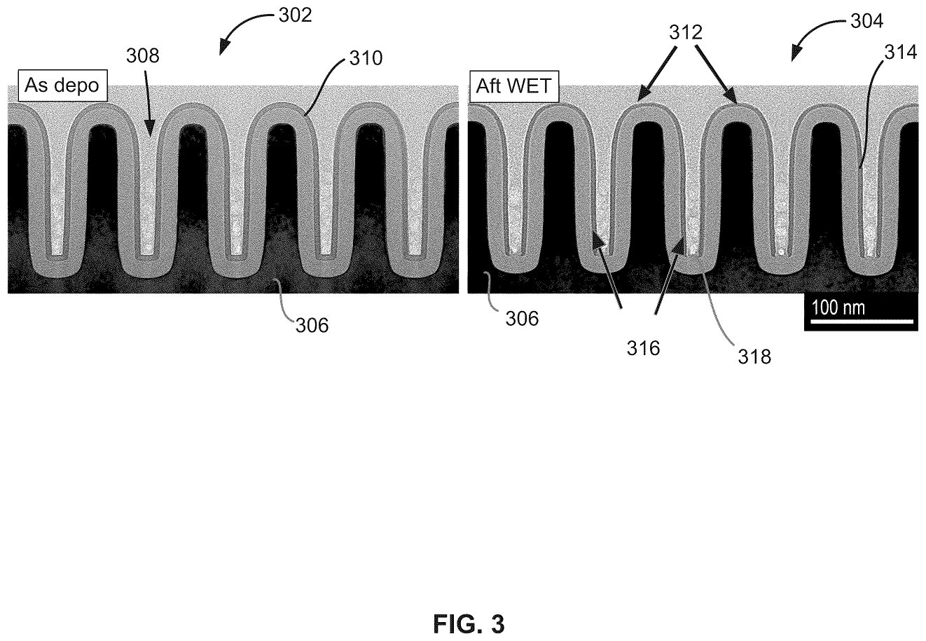

FIG. 3 illustrates transmission electron microscopy images of a structure 302 after step 104 and a structure 304 after step 106. A power level used during the deposition was 1800 W. Structure 302 includes a substrate 306, including a feature 308, such as a gap. Structure 302 includes a layer 310 of silicon nitride conformally deposited (a conformality of a thickness of the silicon nitride overlying the feature is at least 60%) onto feature 308. Structure 304 can be the same as structure 302 after exposure of silicon nitride layer 310 to an etch process. As illustrated, silicon nitride remains at a top 312 and sidewall 316 but is removed from a bottom 318 of the feature (e.g., feature 308). Table 2 below provides as deposited conformality information and wet etch amounts for the structure 304.

TABLE 2

| | | | 1800 W |
|---|---|---|---|
| | | | (w/precursor soak inert gas |
| | Deposition Condition | | activation) |
| As Depo conformality | | | 109 |
| [%] | | | |
| (S90/Top) | | | |
| | WEA [Å] | Top | 20.7 |
| | dHF100:1 | S30 | 10.1 |
| | 3 min dip | S90 | 13.5 |
| | | Bottom | >61.2 |

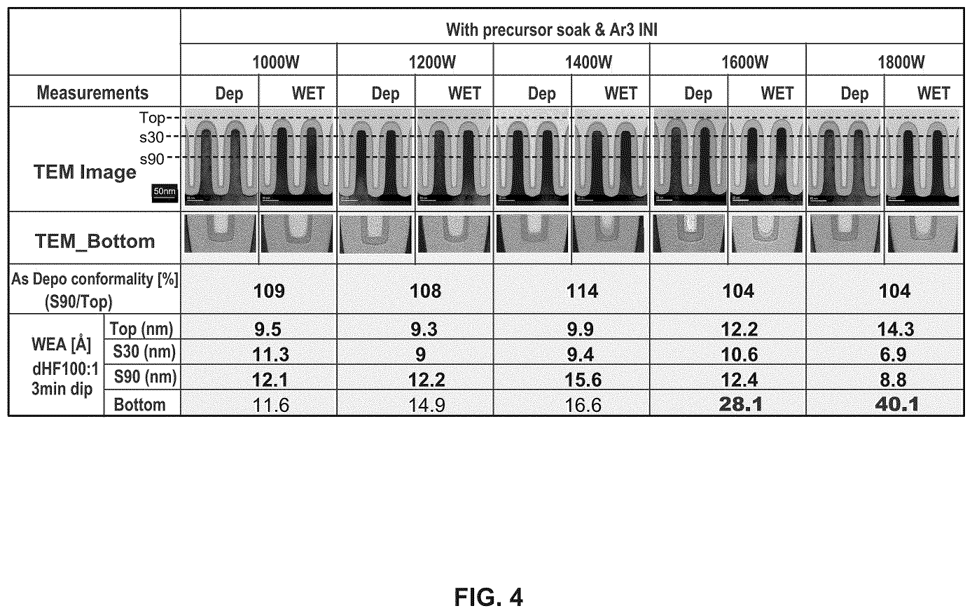

FIG. 4 illustrates conformality and wet etch amount (WEA) for silicon nitride deposited and treated with 1000 W, 1200 W, 1400 W, 1600 W and 1800 W plasma power levels at 60 MHz. Higher RF power gave higher bottom WEA (wet etching amount). From these results, it may be inferred that high ion bombardment energy may cause bottom film quality degradation.

Techniques for forming silicon nitride only on a sidewall, and not a top or a bottom, often include using plasma power having a frequency of 13 MHz. When a 13 MHz generator is used, both top and bottom film quality is degraded by plasma having high ion energy. On the other hand, a (e.g., PEALD) process using greater than 13 MHz (e.g., 60 MHz) generator gave bottom less film profile keeping top and side wall film. The possible factor of giving bottom less profile is ion energy and flux distribution of 60 MHz.

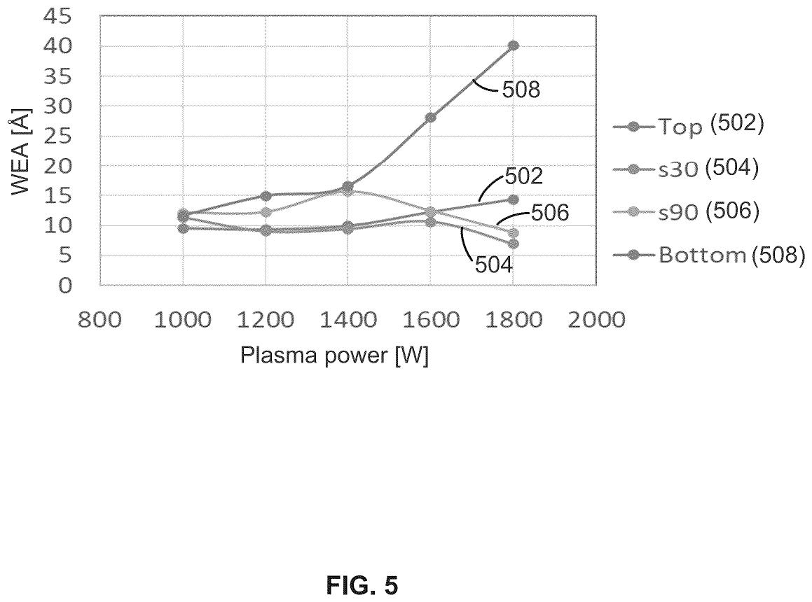

FIG. 5 graphically illustrates results tabulated in FIG. 4. As illustrated, higher plasma power levels produced higher wet etch amounts at a bottom of the feature, relative to the top and sidewall positions of the feature.

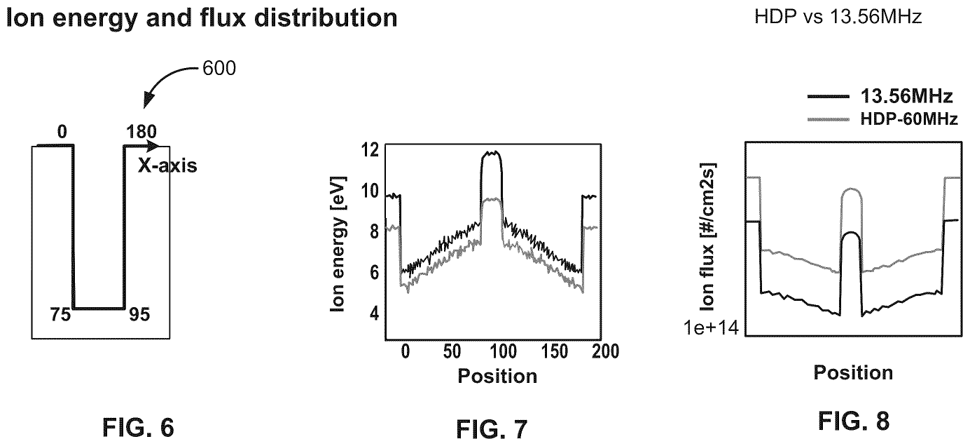

FIGS. 6-8 illustrate two-dimensional ion angle energy distribution function simulation results of ion energy and ion flux distribution for a plasma used for 13.56 MHz power and HDP (e.g., 60 MHz power) provided during deposition and treatment steps as described above. The ion energy and ion flux were calculated using a Monte Marlo method. FIG. 6 illustrates positional information of a feature 600 for use with FIGS. 7 and 8. For the high-frequency (HDP) power, ion energy at the bottom of feature 600 is higher than at the top, because ion scattering occurs at top and ion scattering causes ion energy to decrease. Ion flux at the top of feature 600 is generally higher than at a bottom. Ion energy and flux balance is important for top and bottom film quality control. In the case of 13 MHz, top and bottom ion energy is high, so both film of top and bottom is damaged by ion bombardment, and only side wall film is remaining after etching. In contrast, for frequencies higher than 14 MHz (e.g., about 60 MHz), when bottom ion energy is enough for causing film damage and top ion energy is lower than the bottom ion energy, only bottom film has damage, such that a bottom less profile is achieved after (e.g., wet) etching.

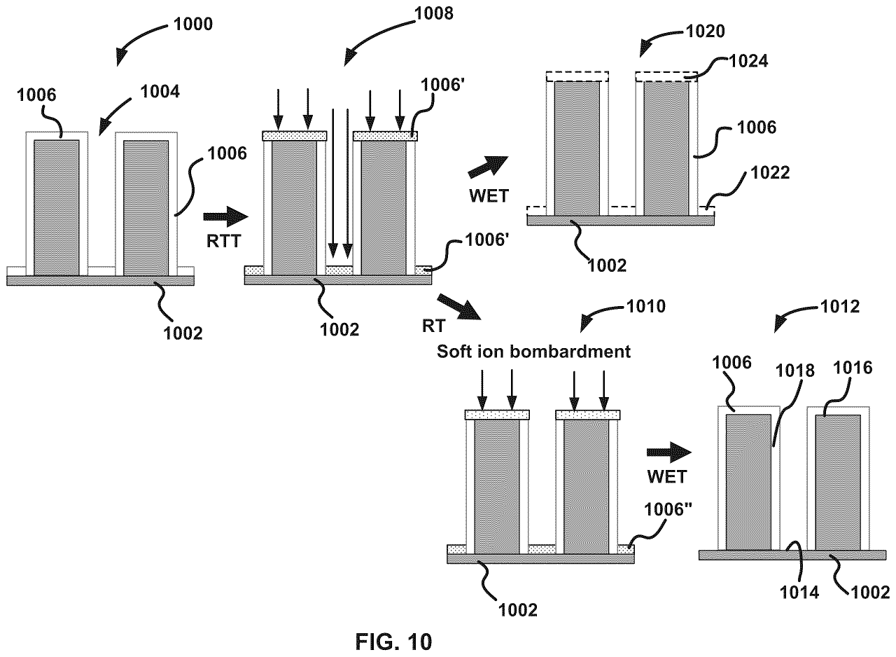

FIGS. 10-12 illustrate additional examples of a method 100 of forming a structure in accordance with yet additional examples of the disclosure. In the examples illustrated in FIGS. 10-12, the treatment process (e.g., treatment process 108) includes two or more steps. In particular, treatment process 108 can include a reverse topological treatment (RTT) step and a reconstruction treatment (RT) step.

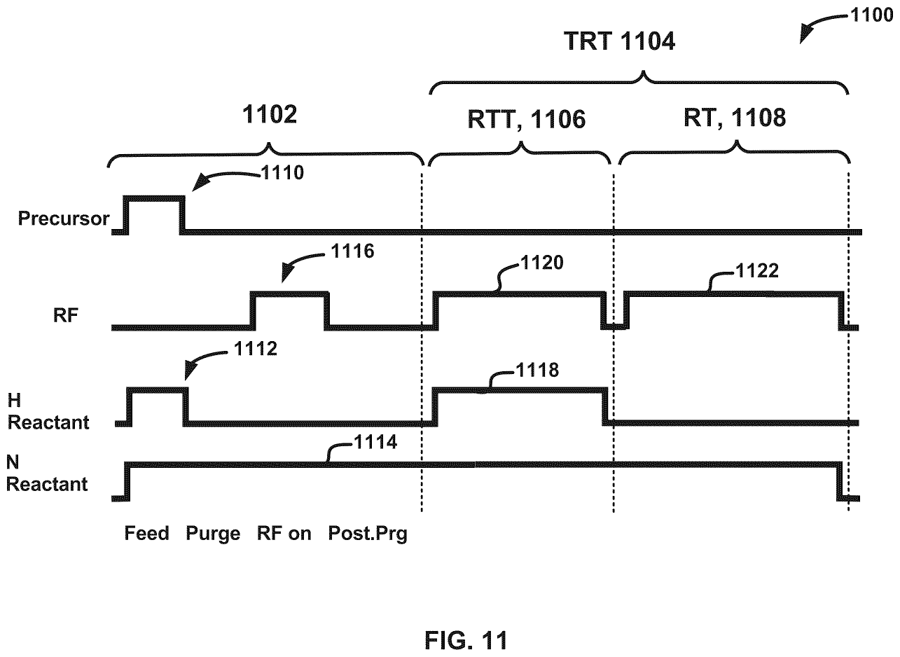

With reference to FIG. 1, in the examples illustrated in FIGS. 10-12, steps 102 and 106 can be as described above. Step 104 can also be as described above. However, in some cases, step 104 can include a process as described below in connection with FIG. 11.

With reference to FIG. 10, after step 104 of method 100, a structure 1000, including a substrate 1002, having one or more features 1004, and a silicon nitride layer 1006 deposited thereon, is exposed to an RTT to form structure 1008 and then an RT to form structure 1010. Structure 1010 can then be exposed to an (e.g., wet) etch process (e.g., step 106) to form a structure 1012 that include a thin or no silicon nitride at a bottom 1014 of a feature 1004, relative to a top 1016 and/or a sidewall 1018 of feature 1004. Without the RT step, a structure 1020 can be formed that includes top and bottom sections 1022, 1024 of treated silicon nitride layer 1006 that are removed during a wet etch process. With RT, only bottom sections 1006″ are removed and SiN on a top surface remains.

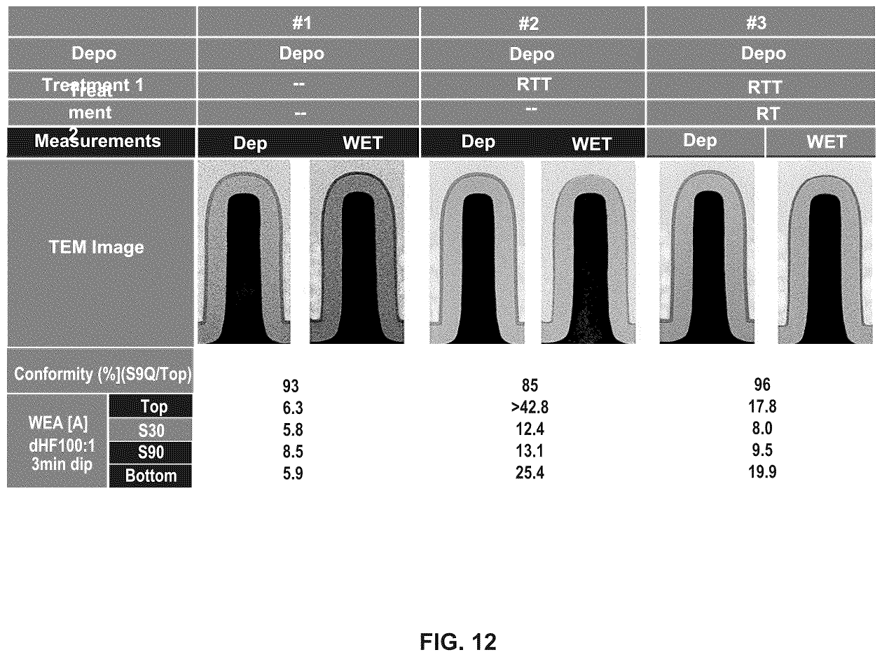

FIG. 11 illustrates a timing sequence 1100 that can be used to form structures illustrated in FIGS. 10 and 12 that is suitable for use with steps 104 and treatment process 108. As illustrated, timing sequence 1100 includes a deposition cycle 1102 and a treatment cycle or process 1104 that includes a RTT 1106 and a RT 1108. Deposition cycle 1102 can correspond to step 104 and treatment process 1104 can correspond to treatment process 108. In accordance with examples of the disclosure, deposition cycle 1102 is repeated one or two or more times (e.g., 5 or more times) prior to timing sequence 1100 proceeding to treatment process 1104. Timing sequence 1100—i.e., one or more deposition cycles 1102 and at least one treatment cycle/process 1104—can also be repeated one or more times prior to method 100 proceeding to step 106. In some cases, the deposited silicon nitride is conformal.

In the illustrated example in FIG. 11, each deposition cycle 1102 includes pulsing or providing a silicon precursor to the reaction chamber for a precursor pulse period (period 1110), providing a hydrogen reactant gas to the reaction chamber (period 1112), providing a nitrogen reactant gas to the reaction chamber (period 1114), and providing a deposition plasma power for a deposition plasma period to form activated species from the reactant gas (period 1116).

During period 1110, the silicon precursor is pulsed to the reaction chamber. Period 1110 can be the same or similar to period 206 described above. The silicon precursor(s) can also be as described above in connection with FIGS. 1 and 2.

During period 1112, a hydrogen-containing reactant is provided to the reaction chamber. Period 1112 and the hydrogen-containing reactant(s) can be as described above in connection with period 214, except a duration of period 1112 can be shorter—e.g., the same or about the same as a duration of period 1110.

During period 1114, a nitrogen-containing reactant is provided to the reaction chamber. The nitrogen-containing reactant(s) can be or include the nitrogen-containing reactant(s) described above in connection with period 212.

A flowrate of the nitrogen-containing reactant to the reaction chamber during period 1114 can be about 1000 to about 50000 sccm or about 10000 to about 30000 sccm. A flowrate of the hydrogen-containing reactant to the reaction chamber during period 1112 can be about 0.1 to about 500 sccm or about 1 to about 300 sccm or about 50 to 150 sccm.

As Illustrated, RTT 1106 includes a period 1114, a period 1118 of providing one or more hydrogen-containing reactant(s) to a reaction chamber, and a period 1120 of providing plasma power. The one or more hydrogen-containing reactant(s) and the one or more nitrogen-containing reactant(s) can be as described above. A flowrate of the one or more hydrogen-containing reactant(s) during a period 1118 can be higher than a flowrate of the one or more hydrogen-containing reactant(s) during 1112. A flowrate of the hydrogen-containing reactant(s) to the reaction chamber during period 1112 can be about 0.1 to about 1000 sccm or about 1 to about 800 sccm or about 200 to 600 sccm. A flowrate of the nitrogen-containing reactant(s) to the reaction chamber during period 1114 can be as described above.

During period 1120, a RTT treatment plasma power is provided for a RTT treatment plasma period 1120 to form activated species from the treatment gas (i.e., the hydrogen-containing reactant(s) provided during period 1118 and the nitrogen-containing reactant(s) provided during period 1114). The RTT treatment plasma power can have a frequency of between about 100 kHz and about 100 MHz and/or between about 40 MHz and about 80 MHz. The treatment plasma power can have a power of between about 10 and about 2000 W or between about 500 and about 150000 W or be about 900 W for a 300 mm diameter substrate or have similar power densities for substrates of different cross-sectional dimensions. A duration of period 218 can be between about 0.05 seconds and about 300 seconds or between about 10 seconds and about 250 seconds. In accordance with examples of the disclosure, the deposition plasma power provided during period 1116 is greater than the treatment plasma power provided during second period 1120. In accordance with further examples, a duration of the deposition plasma period 1116 is less than a duration of period 1120.

RTT 1106 is anisotropic, as illustrated in FIG. 10. During this step, strong ion bombardment is used to treat the silicon nitride layer (e.g., layer 1006) to form regions 1006′ of the silicon nitride layer.

RT 1108 includes a portion of period 1114 and a period 1122 of providing RT plasma power. The one or more nitrogen-containing reactant(s) provided during period 1114 can be as described above. A flowrate of the nitrogen-containing reactant(s) to the reaction chamber during period 1114 can also be as described above.

During period 1122, an RT treatment plasma power is provided for a RT treatment plasma period 1122 to form activated species from the treatment gas (i.e., the nitrogen-containing reactant(s) provided during period 1114) and to form regions 1006″ that may be of lower film quality, relative to the film on the top and sidewalls of features 1004 and therefore more easily removed. During this step, a quality (e.g., etch resistance) of layer 1006 on the top and sidewalls of feature 1004 can be increased. The RT treatment plasma power can have a frequency of between about 100 kHz and about 100 MHz and/or between about 40 MHz and about 80 MHz. The treatment plasma power can have a power of between about 10 and about 2000 W or between about 500 and about 150000 W or be about 900 W for a 300 mm diameter substrate or have similar power densities for substrates of different cross-sectional dimensions. A duration of period 218 can be between about 0.05 seconds and about 300 seconds or between about 10 seconds and about 250 seconds. In some cases, a plasma power during period 1120 and a plasma power during period 1122 can be about the same. In accordance with examples of the disclosure, the deposition plasma power provided during period 1116 is greater than the RT plasma power provided during second period 1122. In accordance with further examples, a duration of the deposition plasma period 1116 is less than a duration of period 1122.

Table 3 below illustrates exemplary conditions for the method and structures illustrated in FIGS. 10-12.

TABLE 3

| Step | Depo | RTT | RT |
|---|---|---|---|
| H2 Feed [sccm] | 100 | — | — |
| H₂ RF ON [sccm] | 0 | 400 | 0 |
| N₂ [slm] | 9.8 | 9.8 | 9.8 |
| CAR N₂ [slm] | 6 | 6 | 6 |
| Seal N₂ [slm] | 3 | 3 | 3 |
| RF power (W) | 140 | 900 | 900 |
| RC Press (Torr) | 7 | 2 | 7 |
| Gap [mm] | 5 | 5 | 5 |
| Feed1 (s) | 2 | — | — |
| Purge(s) | 1.5 | — | — |
| RF on (s) | 1.5 | 180 | 180 |
| H₂ IN (s) | 1.5 | — | — |

FIG. 12 illustrates TEM images of structures before and after WET etching with dHF 100:1 3 min dipping for SiN film deposited on substrates having features with an opening size of 22 nm and an aspect ratio of 7. Condition #1 is SiN depo only, condition #2 includes applied RTT, and condition #3 includes RT after RTT. From the results shown FIG. 12, WEA (wet etched amount) profile of SiN deposition only (condition #1) was only conformal. When RTT was applied, top and bottom WEA was significantly increased (condition #2). Hydrogen can easily penetrate, and the strong anisotropic plasma of RTT might cause the film quality degradation. When RT was applied after RTT, the degraded top and bottom film was recovered by hydrogen removal and nitridation. Reconstruction effect on bottom can be suppressed by using high pressure, because fewer ions reach a bottom of the features. The combination of RTT and RT can make WEA profile of top<bottom, and it can make bottom SiN film thin profile.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a structure, the method comprising:
providing a substrate within a reaction chamber, the substrate comprising a feature on a surface of the substrate, the feature comprising a top, a bottom, and a sidewall therebetween;
using a plasma deposition process, depositing silicon nitride onto the top, the bottom, and the sidewall of the feature; and
selectively removing the silicon nitride at the bottom of the feature relative to the top and the sidewall of the feature.

2. The method of claim 1, wherein after the step of selectively removing the silicon nitride at the bottom, the silicon nitride is removed from the bottom of the feature, and the structure comprises silicon nitride on the top and on the sidewall of the feature.

3. The method of claim 1, wherein the step of selectively removing comprises a wet etch process.

4. The method of claim 3, wherein the wet etch process comprises a dilute hydrofluoric acid etch.

5. The method of claim 1, wherein the plasma deposition process comprises providing power having a frequency between about 13 MHz and about 100 MHz or greater than 14 MHz and less than 100 MHz.

6. The method of claim 1, wherein the plasma deposition process comprises providing power having a power density between 0.01 and about 0.03 W/mm² of substrate size.

7. The method of claim 1, wherein the plasma deposition process comprises providing power between about 800 and about 2000 W.

8. The method of claim 1, wherein the plasma deposition process comprises a cyclical plasma deposition process.

9. The method of claim 8, wherein the cyclical plasma deposition process comprises pulsing a silicon precursor to the reaction chamber for a precursor pulse, providing a reactant gas comprising hydrogen and nitrogen, and after the precursor pulse, providing plasma power within the reaction chamber to form a plasma.

10. The method of claim 9, wherein the reactant gas comprising hydrogen and nitrogen is provided continuously to the reaction chamber through two or more deposition cycles.

11. The method of claim 1, wherein the method further comprises a treatment process.

12. The method of claim 11, wherein two or more deposition cycles are repeated prior to the treatment process.

13. The method of claim 12, wherein the gas comprising hydrogen and nitrogen comprises a nitrogen-containing reactant, and wherein the nitrogen-containing reactant is continuously supplied to the reaction chamber during a plurality of deposition cycles and the treatment process.

14. The method of claim 1, wherein after the plasma deposition process, a conformality of a thickness of the silicon nitride overlying the feature is at least 60%.

15. A method of forming a structure, the method comprising:
providing a substrate within a reaction chamber, the substrate comprising a feature on a surface of the substrate, the feature comprising a top, a bottom, and a sidewall therebetween;
using a plasma deposition process, depositing silicon nitride onto the top, the bottom, and the sidewall of the feature; and
selectively removing the silicon nitride at the bottom of the feature relative to the top and sidewall of the feature, such that the silicon nitride is removed at the bottom of the feature and remains at the top and the sidewall of the feature,
wherein the plasma deposition process comprises providing power having a frequency between about 13 MHz and about 100 MHz.

16. The method of claim 15, wherein the step of selectively removing comprises a wet etch process.

17. The method of claim 15, wherein the plasma deposition process comprises a cyclical plasma deposition process that comprises pulsing a silicon precursor to the reaction chamber for a precursor pulse, providing a reactant gas comprising nitrogen, and after the precursor pulse, providing plasma power within the reaction chamber to form a plasma.

18. The method of claim 15, further comprising a treatment process.

19. The method of claim 18, wherein the treatment process comprises a reverse topological treatment step.

20. The method of claim 19, wherein the treatment process further comprises a reconstruction treatment step.
